(19) United States
(12) Patent Application Publication
(10) Pub. No.: US 2025/0014925 A1
(43) Pub. Date: Jan. 9, 2025

(54) INFORMATION PROCESSING APPARATUS, ABNORMALITY DETECTION METHOD, AND SEMICONDUCTOR MANUFACTURING SYSTEM

(71) Applicant: Tokyo Electron Limited, Tokyo (JP)

(72) Inventors: Yuka NAKASATO, Yamanashi (JP); Masahiro YANAGISAWA, Yamanashi (JP); Huizhen BU, Tokyo (JP)

(21) Appl. No.: 18/759,466

(22) Filed: Jun. 28, 2024

(30) Foreign Application Priority Data
Jul. 6, 2023 (JP) 2023-111151

(51) Int. Cl. H01L 21/67; G01M 99/00

(52) U.S. Cl. CPC H01L 21/67253; G01M 99/005

(57) ABSTRACT

An information processing apparatus includes an acquisition unit that acquires a plurality of sensor values output from a plurality of sensors installed in a semiconductor manufacturing apparatus while a process is running; an inference unit that infers an abnormality degree of the process from the acquired sensor values, using an abnormality detection model that has learned a correspondence relationship between the sensor values and the abnormality degree of the process using learning data; an abnormality detection unit that detects an abnormality occurring in the process based on the inferred abnormality degree of the process; and an abnormality factor search unit that searches for a univariate abnormality and a correlation abnormality that are candidates of abnormality factors occurring in the process, using abnormality factor search methods; and an abnormality determination result output unit that outputs the detected abnormality and the searched univariate abnormality and correlation abnormality, as an abnormality determination result.

### CROSS-REFERENCE TO RELATED APPLICATIONS

This application is based on and claims priority from Japanese Patent Application No. 2023-111151 filed on Jul. 6, 2023, with the Japan Patent Office, the disclosure of which is incorporated herein in its entirety by reference.

### TECHNICAL FIELD

The present disclosure relates to an information processing apparatus, an abnormality detection method, and a semiconductor manufacturing system.

### BACKGROUND

As an abnormality detection method of a semiconductor manufacturing apparatus, for example, a method for generating a multivariate analysis model expression has been known in the related art where the state of a processing apparatus is evaluated or a processing result is predicted by multivariate analysis (see, e.g., Japanese Patent No. 4224454).

In Japanese Patent No. 4224454, a correlation between setting data and detected data that have been detected from a plurality of sensors of a processing apparatus when the processing apparatus is operated based on the setting data is obtained for each of a plurality of processing apparatuses through multivariate analysis, so that a multivariate analysis model expression is generated for evaluating the state of the processing apparatus, or predicting a processing result.

### SUMMARY

An aspect of the present disclosure provides an information processing apparatus for abnormality detection of a semiconductor manufacturing apparatus. The information processing apparatus includes an acquisition unit that acquires a plurality of sensor values output from a plurality of sensors installed in the semiconductor manufacturing apparatus, while a process is running; an inference unit that infers an abnormality degree of the process from the plurality of sensor values acquired by the acquisition unit, using an abnormality detection model that has learned a correspondence relationship between the plurality of sensor values and the abnormality degree of the process using learning data; an abnormality detection unit that detects an abnormality occurring in the process based on the inferred abnormality degree of the process; and an abnormality factor search unit that searches for a univariate abnormality and a correlation abnormality that are candidates of abnormality factors occurring in the process, by using a plurality of abnormality factor search methods; and an abnormality determination result output unit that outputs the detected abnormality and the searched univariate abnormality and correlation abnormality, as an abnormality determination result.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a configuration of a semiconductor manufacturing system according to an embodiment of the present disclosure.

FIG. 2 illustrates a hardware configuration of a computer according to an embodiment of the present disclosure.

FIG. 3 is a functional block diagram of a semiconductor manufacturing apparatus according to an embodiment of the present disclosure.

FIG. 4 illustrates a generating sequence of an abnormality detection model completed with learning.

FIG. 5 is a flowchart illustrating an abnormality detection sequence using the learned abnormality detection model according to an embodiment of the present disclosure.

FIG. 6 illustrates a processing sequence of detecting an abnormality occurring in a process.

FIG. 7 illustrates a processing sequence of abnormality factor searching.

FIG. 8 illustrates an abnormality detection model that is generated for each section of a process.

FIG. 9 illustrates a table displaying an abnormality degree for each run and each section.

FIG. 10 illustrates calculation of a maximum deviation.

FIG. 11 illustrates an example of searching for candidates of abnormality factors in a semiconductor manufacturing system according to an embodiment of the present disclosure.

FIG. 12 illustrates an example of searching for candidates of abnormality factors in a semiconductor manufacturing system according to an embodiment of the present disclosure.

FIG. 13 illustrates an example of searching for candidates of abnormality factors in a semiconductor manufacturing system according to an embodiment of the present disclosure.

FIG. 14 illustrates an example of searching for candidates of abnormality factors in a semiconductor manufacturing system according to an embodiment of the present disclosure.

### DETAILED DESCRIPTION

In the following detailed description, reference is made to the accompanying drawings, which form a part thereof. The illustrative embodiments described in the detailed description, drawings, and claims are not meant to be limiting. Other embodiments may be used, and other changes may be made without departing from the spirit or scope of the subject matter presented here.

Hereinafter, various embodiments of the present disclosure will be described with reference to the drawings.

### <System Configuration>

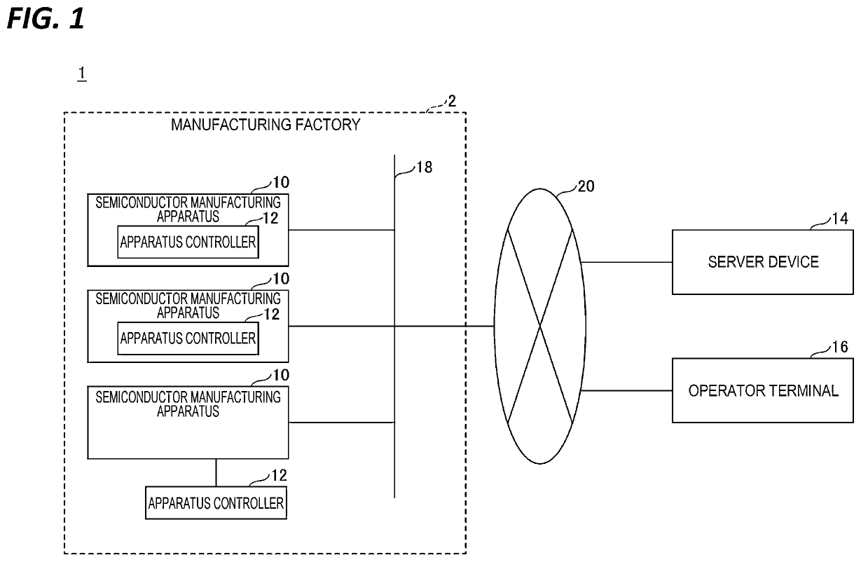

FIG. 1 illustrates a configuration of a semiconductor manufacturing system according to an embodiment of the present disclosure. A semiconductor manufacturing system 1 of FIG. 1 includes a semiconductor manufacturing apparatus 10, an apparatus controller 12, a server device 14, and an operator terminal 16. The semiconductor manufacturing apparatus 10 and the apparatus controller 12 are installed in a manufacturing factory 2. The server device 14 and the operator terminal 16 may be installed in the manufacturing factory 2 or may be installed outside of the manufacturing factory 2. The operator terminal 16 is operated by an operator such as an apparatus operator or an analysis operator of the semiconductor manufacturing apparatus 10 installed in the manufacturing factory 2.

The semiconductor manufacturing apparatus 10, the apparatus controller 12, the server device 14, and the operator terminal 16 are communicatively connected via networks 18 and 20, such as the Internet and a local area network (LAN).

The semiconductor manufacturing apparatus 10 is an apparatus that performs processing, such as, for example, film forming processing, etching processing, or ashing processing, and processes a semiconductor wafer or a glass substrate of a flat panel display. The semiconductor manufacturing apparatus 10 is, for example, a substrate processing apparatus, a heat treatment apparatus, or a film forming apparatus. The semiconductor manufacturing apparatus 10 receives control instructions according to a recipe, from the apparatus controller 12, and executes a process. The semiconductor manufacturing apparatus 10 is equipped with a plurality of sensors.

The semiconductor manufacturing apparatus 10 may be installed in the semiconductor manufacturing apparatus 10 as illustrated in FIG. 1, or may not necessarily be installed in the semiconductor manufacturing apparatus 10, as long as they are communicatively connected. The apparatus controller 12 includes a computer that controls the semiconductor manufacturing apparatus 10. The apparatus controller 12 outputs control instructions to control components of the semiconductor manufacturing apparatus 10 according to the recipe, thereby executing a process according to the recipe on the semiconductor manufacturing apparatus 10.

The apparatus controller 12 has a function of a man-machine interface that receives instructions for the semiconductor manufacturing apparatus 10 from an operator and provides information about the semiconductor manufacturing apparatus 10 to the operator. The apparatus controller 12 receives sensor values output from the plurality of sensors installed in the semiconductor manufacturing apparatus 10. The sensors include, for example, a temperature sensor, a pressure sensor, and a flow rate sensor. The apparatus controller 12 is an example of an information processing apparatus that performs abnormality detection of the semiconductor manufacturing apparatus 10.

The server device 14 may receive the sensor values output from the plurality of sensors installed in the semiconductor manufacturing apparatus 10 and store them as a process log. The server device 14 is an example of an information processing apparatus that performs abnormality detection of the semiconductor manufacturing apparatus 10.

In addition, the apparatus controller 12 or the server device 14 may display a result of the abnormality detection on a display of the apparatus controller 12, a display of the server device 14, or a display of the operator terminal 16 to notify the result of the abnormality detection to an operator. When detecting an abnormality in the semiconductor manufacturing apparatus 10, the apparatus controller 12 or the server device 14 may notify the operator of the abnormality using e-mail.

The operator terminal 16 is a personal computer (PC) or a smartphone operated by an operator such as an apparatus operator or an analysis operator of the semiconductor manufacturing apparatus 10 installed in the manufacturing factory 2.

The semiconductor manufacturing system 1 of FIG. 1 is provided by way of an example, and examples of various system configurations may be provided depending on a use or purpose. For example, the semiconductor manufacturing system 1 may have various configurations, such as a configuration in which apparatus controllers 12 of individual semiconductor manufacturing apparatuses 10 are integrated into an apparatus controller for a plurality of semiconductor manufacturing apparatuses 10 or a configuration in which the apparatus controller is further divided.

### <Hardware Configuration>

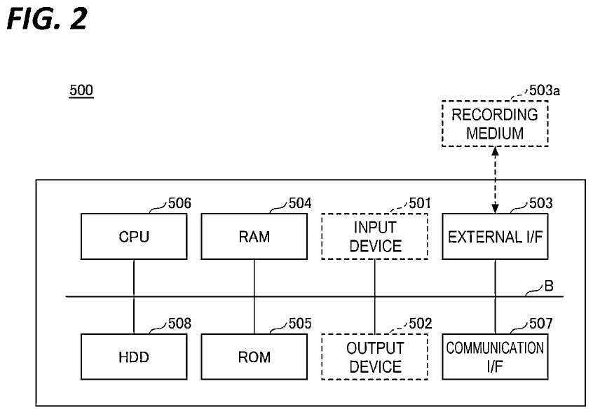

The apparatus controller 12, the server device 14, and the operator terminal 16 of the semiconductor manufacturing system 1 as illustrated in FIG. 1 are implemented by a computer (information processing apparatus) with a hardware configuration illustrated in FIG. 2, for example. FIG. 2 illustrates a hardware configuration of a computer.

A computer 500 illustrated in FIG. 2 includes an input device 501, an output device 502, an external IF (interface) 503, a random access memory (RAM) 504, a read only memory (ROM) 505, a central processing unit (CPU) 506, a communication I/F 507, and a hard disk drive (HDD) 508, each of which is interconnected by a bus B. Further, the input device 501 and the output device 502 may be connected and used as needed.

The input device 501 is a keyboard, a mouse, or a touch panel and is used to input each operational signal by an operator. The output device 502 is a display and displays a result of processing by the computer 500. The communication I/F 507 is an interface that connects the computer 500 to the network 18 or 20. The HDD 508 is an example of a non-volatile storage device that stores programs or data.

The external I/F 503 is an interface to an external device. The computer 500 may perform reading and/or recording on a recording medium 503a, such as a secure digital (SD) memory card, via the external I/F 503. The ROM 505 is an example of a non-volatile semiconductor memory (storage device) in which programs or data are stored. The RAM 504 is an example of a volatile semiconductor memory (storage device) that temporarily holds programs or data.

The CPU 506 is a computing device that reads programs or data from the storage device such as the ROM 505 or the HDD 508 and executes a processing to implement control or functions of the entire computer 500.

The apparatus controller 12, the server device 14, and the operator terminal 16 of FIG. 1 may implement various functions to be described below by executing a program with the computer 500 with the hardware configuration as illustrated in FIG. 2.

### <Functional Configuration>

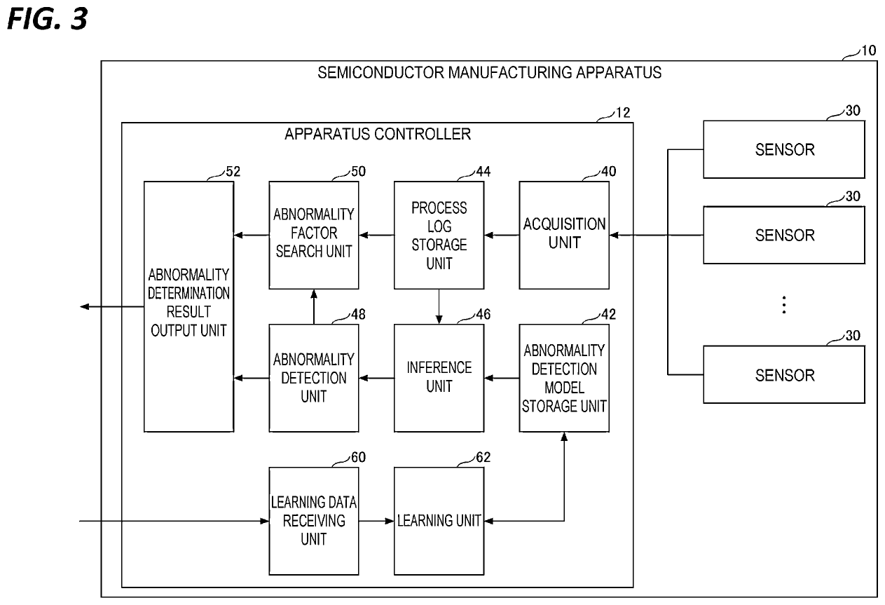

The semiconductor manufacturing apparatus 10 of the semiconductor manufacturing system 1, according to an embodiment of the present disclosure, is implemented as functional blocks, for example, as illustrated in FIG. 3. FIG. 3 is a functional block diagram of a semiconductor manufacturing apparatus according to an embodiment of the present disclosure. The functional block diagram in FIG. 3 does not illustrate configurations that are unnecessary for the description of the embodiment.

The apparatus controller 12 of the semiconductor manufacturing apparatus 10 in FIG. 3 implements an acquisition unit 40, an abnormality detection model storage unit 42, a process log storage unit 44, an inference unit 46, an abnormality detection unit 48, an abnormality factor search unit 50, an abnormality determination result output unit 52, a learning data receiving unit 60, and a learning unit 62, by executing a program for the apparatus controller 12.

A plurality of sensors 30 are installed in the semiconductor manufacturing apparatus 10 and output a plurality of sensor values during a running of a process. The plurality of sensors 30 include, for example, a temperature sensor, a pressure sensor, and a flow rate sensor. The acquisition unit 40 of the apparatus controller 12 acquires the plurality of sensor values output during the running of the process from the plurality of sensors 30. The process log storage unit 44 stores the plurality of sensor values output from the plurality of sensors 30 during the running of the process as a process log for each run of the process.

The inference unit 46 infers an abnormality degree of the process from the plurality of sensor values of the plurality of sensors 30 included in the process log, by using an abnormality detection model that has learned a correspondence relationship between the plurality of sensor values of the plurality of sensors 30 and the abnormality degree of the process by learning data. The abnormality detection model is stored in the abnormality detection model storage unit 42.

The learning data receiving unit 60 receives learning data that is used to train the abnormality detection model by the learning unit 62. The learning data receiving unit 60 may receive the learning data from, for example, the server device 14, or from the computer 500.

By the learning unit 62, the abnormality detection model learns the correspondence relationship between the plurality of sensor values of the plurality of sensors 30 and the abnormality degree of the process, by using the learning data. Further, the learning of the abnormality detection model by the learning unit 62 will be described in detail below.

The abnormality detection unit 48 detects an abnormality occurring in the process based on the abnormality degree of the process, which is inferred by the inference unit 46. The abnormality detection unit 48 detects an abnormality occurring in the process when the abnormality degree of the process inferred by the inference unit 46 is included in an abnormality range, as described below. Also, the detection of abnormality by the abnormality detection unit 48 will be described later.

The abnormality factor search unit 50 searches for a univariate abnormality and a correlation abnormality that are candidates of abnormality factors occurring in a process, using a plurality of abnormality factor search methods as described below, for the process where an abnormality has been detected by the abnormality detection unit 48.

The abnormality determination result output unit 52 outputs the abnormality detected by the abnormality detection unit 48 and the univariate abnormality and the correlation abnormality detected by the abnormality factor search unit 50 as an abnormality determination result. The abnormality determination result output unit 52 issues a warning or reports an abnormality to notify an operator of the abnormality determination result. The notification to the operator may be displayed on a display or may be performed by e-mailing or by printing.

The functional block diagram in FIG. 3 is provided by way of an example, and the learning data receiving unit 60 and the learning unit 62 may be installed in the computer 500 other than the apparatus controller 12. For example, the learning data receiving unit 60 and the learning unit 62 may be installed in the server device 14.

The acquisition unit 40, the abnormality detection model storage unit 42, the process log storage unit 44, the inference unit 46, the abnormality detection unit 48, the abnormality factor search unit 50, the abnormality determination result output unit 52, the learning data receiving unit 60, and the learning unit 62, in the functional block diagram of FIG. 3 may be installed in the server device 14. The functional block diagram in FIG. 3 illustrates an example in which the apparatus controller 12 is installed in the semiconductor manufacturing apparatus 10, but the apparatus controller 12 may not be installed in the semiconductor manufacturing apparatus 10 as long as they are communicatively connected.

To minimize product damage in the semiconductor manufacturing apparatus 10, it is necessary to detect an abnormality at a time when the abnormality occurs. In addition, since the semiconductor manufacturing apparatus 10 is equipped with the plurality of sensors 30, it is necessary to comprehensively monitor the sensors 30. Therefore, in the semiconductor manufacturing apparatus 10, detection of abnormality is performed by a multivariate abnormality detection method. The multivariate abnormality detection method calculates an abnormality degree (target variable) from sensor values (explanatory variables) of the plurality of sensors 30 using machine learning and considers that an abnormality has occurred when the abnormality degree exceeds a threshold value.

When an abnormality occurs in the semiconductor manufacturing apparatus 10, it is necessary for an operator to promptly identify where and what kind of abnormality has occurred in the semiconductor manufacturing apparatus 10 in order to timely restore the semiconductor manufacturing apparatus 10. However, in the multivariate abnormality detection method, since an abnormality degree is calculated by adding a change in the relationship of the sensor values of the plurality of sensors 30, it is difficult to analyze the cause of the abnormality, e.g., it is difficult to examine the abnormality factor.

Thus, the embodiment of the present disclosure combines the multivariate abnormality detection by the abnormality detection model with the abnormality factor search method, and present and visualize the correlation of a single sensor 30 and the plurality of sensors 30 that are the candidates of abnormality factors, as described below.

### <Processing>

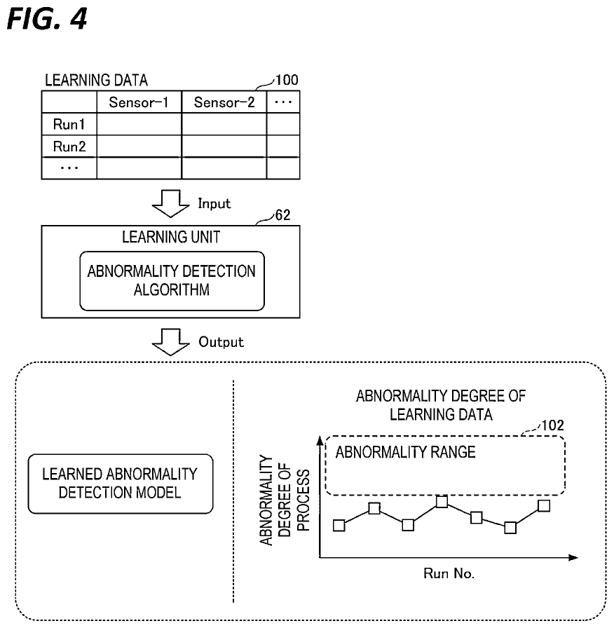

The semiconductor manufacturing system 1 of the embodiment generates an abnormality detection model completed with learning in sequence, for example, as illustrated in FIG. 4. FIG. 4 illustrates a generating sequence of an abnormality detection model completed with learning. The generation of the learned abnormality detection model may be performed in the apparatus controller 12, or may be performed in the server device 14 and registered in the apparatus controller 12 of the semiconductor manufacturing apparatus 10. Here, an example of performing an operation in the apparatus controller 12 illustrated in FIG. 3 is described below.

The learning data receiving unit 60 of the apparatus controller 12 receives the learning data 100 that is used in learning of the abnormality detection model by the learning unit 62. In the learning data 100, the plurality of sensors 30 installed in the semiconductor manufacturing apparatus 10 and sensor values for each run of the process, which are output from the plurality of sensors 30 during the running of the process correspond to each other. “Run 1” and “Run 2” of the learning data 100 are identification information of runs of the process. “Sensor-1” and “Sensor-2” of the learning data 100 are identification information of the plurality of sensors 30.

The learning unit 62 trains a known abnormality detection algorithm with the learning data 100 in a normal state, thereby generating an abnormality detection model completed with learning (e.g. a learned abnormality detection model). The learning data 100 in a normal state may be sensor values output from the plurality of sensors 30 when the semiconductor manufacturing apparatus 10 where no abnormality occurs is running a process.

Based on an abnormality degree of the process during each running (hereinafter, referred to as run) of the process that is output when the learning data 100 in the normal state is input to the learned abnormality detection model, the learning unit 62 may prepare an abnormality range 102 of abnormality degrees of the process.

In the following inference, when an abnormality degree of the process output from the learned abnormality detection model is included in the abnormality range 102, the abnormality detection unit 48 may detect an abnormality occurring in the process.

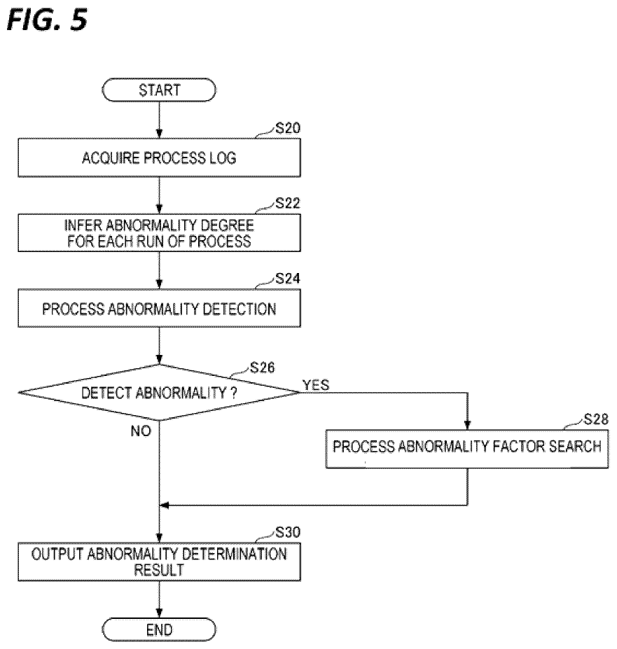

The semiconductor manufacturing system 1 of the embodiment performs abnormality detection of the semiconductor manufacturing apparatus 10 in sequence as illustrated in FIG. 5, for example. FIG. 5 is a flow chart illustrating an abnormality detection sequence using the learned abnormality detection model according to an embodiment of the present disclosure.

In step S20, the acquisition unit 40 of the apparatus controller 12 acquires a plurality of sensor values output from the plurality of sensors 30 during the running of the process as a process log for each run. In the process log, the plurality of sensors 30 installed in the semiconductor manufacturing apparatus 10, and the sensor values for each run, which are output from the plurality of sensors 30 during the running of the process, correspond to each other.

In step S22, the inference unit 46 infers an abnormality degree of the process for each run from the plurality of sensor values for each run of the plurality of sensors 30 included in the process log, by using the learned abnormality detection model. Further, in step S24, the abnormality detection unit 48 detects an abnormality that has occurred in the process based on the abnormality degree of the process which is inferred by the inference unit 46.

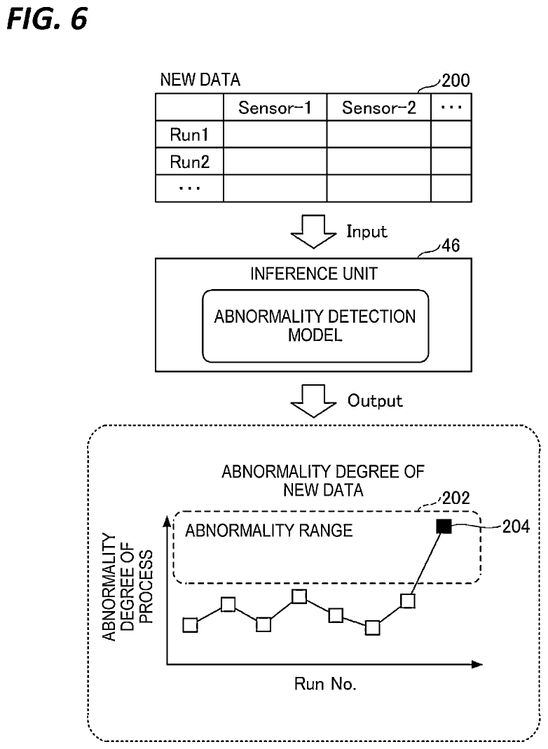

Processing operations of steps S20 to S24 are performed, for example, in sequence as illustrated in FIG. 6. FIG. 6 illustrates a processing sequence of detecting an abnormality occurring in the process.

In step S20, the acquisition unit 40 acquires new data 200 which is a process log of new run, when the new Run is executed. In step S22, the inference unit 46 infers an abnormality degree of the new data 200 from sensor values of the plurality of sensors 30 included in the new data 200, by using the learned abnormality detection model.

A graph in the bottom of FIG. 6 illustrates a plot of an abnormality degree of a process for each run number (Run No.). In addition, a plot 204 of the graph illustrates the inferred abnormality degree of the process of the new data 200. In addition, the graph of FIG. 6 illustrates an example where the plot 204 of the new data 200 is included in an abnormality range 202.

When the abnormality degree of the process inferred by the inference unit 46 is included in the abnormality range 202, the abnormality factor search unit 50 proceeds from step S26 to step S28. When the abnormality degree of the process inferred by the inference unit 46 is not included in the abnormality range 202, the abnormality factor search unit 50 proceeds from step S26 to step S30.

In step S28, the abnormality factor search unit 50 searches for a univariate abnormality and a correlation abnormality that are candidates of abnormality factors occurring in the process, using a plurality of abnormality factor search methods, for the process where an abnormality has been detected by the abnormality detection unit 48.

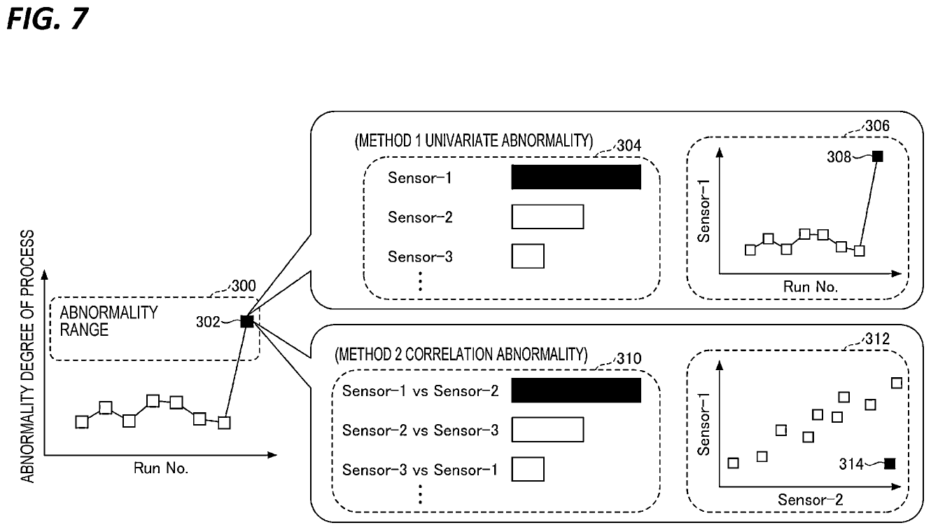

FIG. 7 illustrates a processing sequence of abnormality factor searching. A graph on a left side of FIG. 7 illustrates an example where a plot 302 of an inferred abnormality degree in the process of the new data 200 is included in an abnormality range 300. The abnormality factor search unit 50 searches for a univariate abnormality and a correlation abnormality of the sensors 30, which are abnormality factors, using a plurality of abnormality factor search methods, for the run of the plot 302 where an abnormality has been detected, and outputs, for example, a ranking and a graph.

“Method 1. Univariate Abnormality” illustrated in FIG. 7 is an example of outputting the univariate abnormality searched for the Run of the plot 302 where an abnormality has been detected, as a ranking 304 and a graph 306 of the sensor 30. The ranking 304 calculates, for the run of the plot 302 where the abnormality has been detected, a deviation of each of the sensor values of the plurality of sensors 30 from a sensor value in a normal state, and displays identification information such as names of the sensors 30 in order of greater deviations. In the ranking 304 of FIG. 7, “Sensor-1” is output as the sensor 30 with a greatest deviation. In addition, the graph 306 illustrates a change in deviation for each run number (Run No.) of the sensor 30 with the greatest deviation. A plot 308 of the graph 306 illustrates a deviation of “Sensor-1” for the run where an abnormality has been detected. As described above, the graph 306 may display a graph of the sensor 30 with a great deviation. The graph 306 may display a plurality of graphs ranked in order of greater deviations or may display a graph selected by a user from the ranking 304.

According to the “Method 1. Univariate Abnormality” illustrated in FIG. 7, since it is possible to visually output a change in the sensor value for each run of the sensor 30 that has the greatest deviation from the sensor value in the normal state, an operator may easily search for an abnormality factor. In addition, since it is possible to visually output a change for each run of the sensor value of the sensor 30 ranked high in the deviation from the sensor value in the normal state or the sensor value of the sensor 30 selected by a user from the ranking 304, an operator may easily search for an abnormality factor.

“Method 2. Correlation Abnormality” illustrated in FIG. 7 is an example of outputting a correlation abnormality searched for the run of the plot 302 where the abnormality has been detected, as a ranking 310 and a graph 312 of a correlation between the sensors 30. The ranking 310 calculates a relationship between the sensor values of every two sensors 30 for the run of plot 302 where the abnormality has been detected, and displays identification information such as the names of the two sensors 30 in order of greater deviations from a relationship in a normal state. In the ranking 310 of FIG. 7, “Sensor-1 vs. Sensor-2” is output as the two sensors 30 having the greatest deviation from the relationship in the normal state.

The graph 312 outputs, for each run, the relationship between the sensor values of “Sensor-1” and “Sensor-2,” which are the two sensors 30 with the greatest deviation from the relationship in the normal state. A plot 314 of the graph 312 illustrates the relationship between the sensor values of “Sensor-1” and “Sensor-2” in the run where the abnormality has been detected. As described above, the graph 312 may display a graph of the relationship between two sensors 30 with a great deviation. The graph 312 may display multiple graphs of the relationship between two sensors 30 ranked high in the deviation, or may display a graph of the relationship between two sensors 30 selected by a user from the ranking 310.

According to the “Method 2. Correlation Abnormality” illustrated in FIG. 7, since it is possible to visually output a change for each run in a correlation between the two sensors 30 with the greatest deviation from a relationship between the sensors 30 in the run in a normal state, an operator may easily search for an abnormality factor. In addition, it is also possible to visually output a change for each run in a correlation of two sensors 30 ranked high in deviation from the relationship between the sensors 30 in the run in the normal state, or a correlation of two sensors 30 selected by a user from the ranking 310, an operator may easily search for an abnormality factor.

As described above, the abnormality factor search unit 50 may search for a univariate abnormality and a correlation abnormality that are candidates of abnormality factors occurring in the process, using a plurality of abnormality factor search methods, for the process where an abnormality has been detected by the abnormality detection unit 48, thereby searching for not only a change in the sensor value of a single sensor 30, but also a change in the correlation between the sensor values of the sensors 30 as the abnormality factors.

Therefore, according to the semiconductor manufacturing system 1 of the embodiment, candidates of abnormality factors are searched for by taking into consideration not only the change in the sensor value of a single sensor 30 but also the change in the correlation between the sensor values of two sensors 30, so that abnormalities caused by various factors may be easily searched for, and early recovery of the semiconductor manufacturing apparatus 10 may be expected when an abnormality occurs.

Returning back to FIG. 5, when proceeding from step S26 to step S30, the abnormality determination result output unit 52 outputs an abnormality determination result indicating that no abnormality has occurred in the process of the new data 200, based on a result of abnormality detection processing in step S24. When proceeding from step S28 to step S30, the abnormality determination result output unit 52 outputs an abnormality determination result indicating that an abnormality has occurred in the process of the new data 200, based on the result of the abnormality detection processing in step S24 and a result of the abnormality factor search processing in step S28.

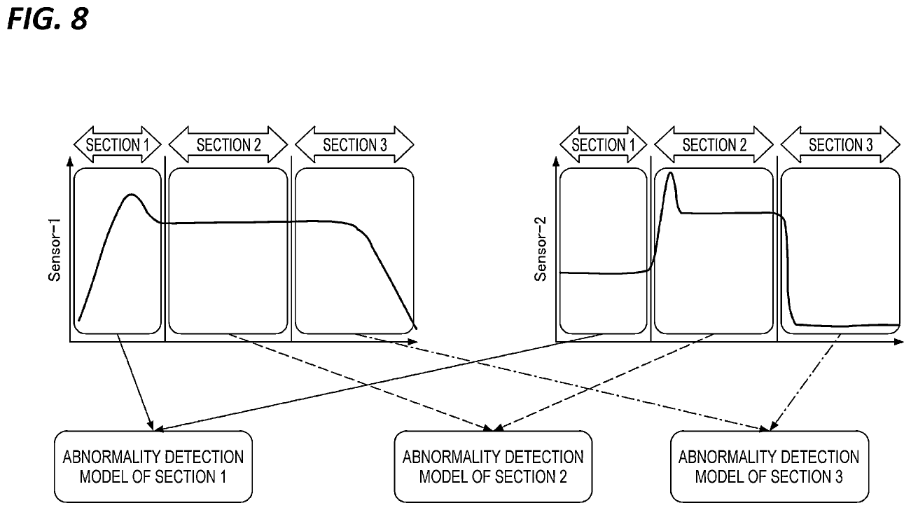

In the semiconductor manufacturing system 1 according to the embodiment, for example, as illustrated in FIG. 8, a process may be divided into a plurality of sections and an abnormality detection model may be generated for each section. FIG. 8 illustrates an abnormality detection model that is generated for each section of the process.

FIG. 8 illustrates an example of dividing a process into three “sections 1” to “section 3” with different processing contents, and generating an “abnormality detection model of section 1,” an “abnormality detection model of section 2,” or an “abnormality detection model of section 3” for each section. The sections may also be referred to as stages.

The “abnormality detection model of section 1” in FIG. 8 performs machine learning on a correspondence relationship between the sensor values of the plurality of sensors 30 and abnormality degrees of the process in “section 1” in FIG. 8. The “abnormality detection model of section 2” in FIG. 8 performs machine learning on a correspondence relationship between the sensor values of the plurality of sensors 30 and abnormality degrees of the process in “section 2” in FIG. 8. The “abnormality detection model of section 3” in FIG. 8 performs machine learning on a correspondence relationship between the sensor values of the plurality of sensors 30 and abnormality degrees of the process in “section 3” in FIG. 8.

The inference unit 46 infers an abnormality degree of the process from sensor values of the plurality of sensors 30 in “Section 1” included in the process log, using an abnormality detection model that has learned a correspondence relationship between sensor values of the plurality of sensors 30 in “Section 1” of FIG. 8 and the abnormality degrees of the process. The inference unit 46 infers an abnormality degree of the process from sensor values of the plurality of sensors 30 in “Section 2” included in the process log, using an abnormality detection model that has learned a correspondence relationship between sensor values of the plurality of sensors 30 in “Section 2” of FIG. 8 and the abnormality degrees of the process. The inference unit 46 infers an abnormality degree of the process from sensor values of the plurality of sensors 30 in “Section 3” included in the process log, using an abnormality detection model that has learned a correspondence relationship between sensor values of the plurality of sensors 30 in “Section 3” of FIG. 8 and the abnormality degrees of the process.

The abnormality detection unit 48 detects an abnormality that has occurred in “Section 1” to “Section 3” of the process, based on abnormality degrees of “Section 1” to “Section 3” of the process, which are inferred by the inference unit 46. The abnormality factor search unit 50 searches for a univariate abnormality and a correlation abnormality that are candidates of abnormality factors occurring in the sections of the process, using a plurality of abnormality factor search methods, for the sections of the process where an abnormality has been detected by the abnormality detection unit 48.

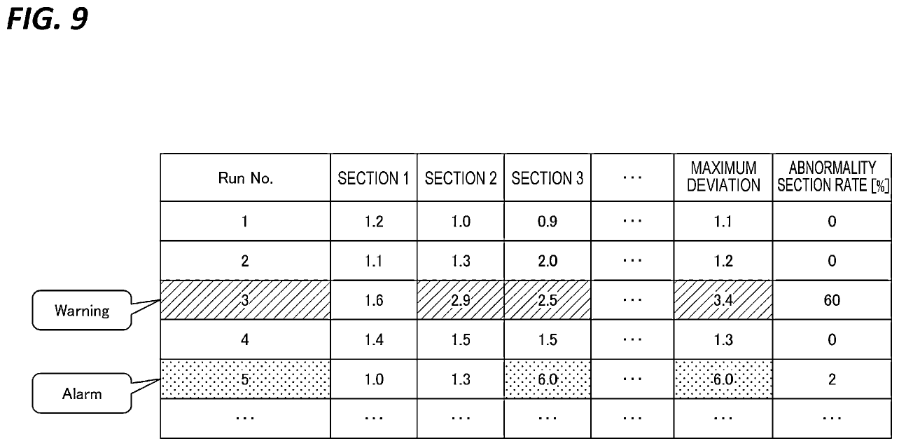

When a process is divided into a plurality of sections, an abnormality detection model is generated for each section, an abnormality degree in the section of the process is inferred, and an abnormality that has occurred in the section of the process is detected, the abnormality determination result output unit 52 may display the abnormality degree for each run and each section, for example, as illustrated in FIG. 9. FIG. 9 illustrates a table displaying an abnormality degree for each run and each section.

The table illustrated in FIG. 9 indicates an abnormality degree of the section of the process for each run number, a maximum deviation, and an abnormality section rate [%]. For example, in FIG. 9, based on a magnitude of the abnormality degree in the section of the process, an abnormality degree range of Warning and Alarm is specified, and a display of a section where the abnormality degree falls within the abnormality degree range of the Warning and Alarm is visually changed from a display of the section where the abnormality degree does not fall within the abnormality degree range of the Warning and Alarm.

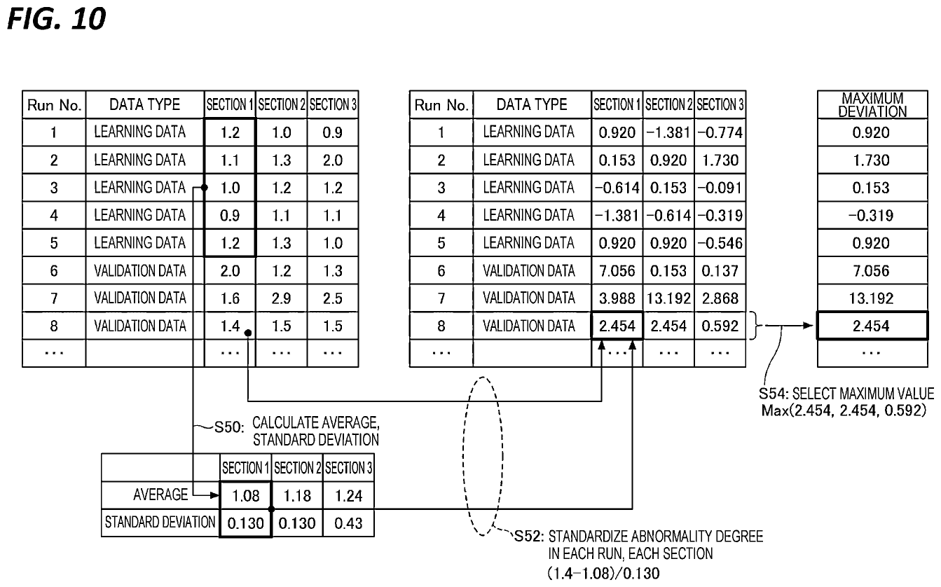

The maximum deviation refers to the greatest deviation in all of sections, among deviations in all of the sections of the process, which are numerical values indicating how abnormal the section is compared to learning data (normal data) in a normal state. The maximum deviation is calculated, for example, as illustrated in FIG. 10.

FIG. 10 illustrates calculation of a maximum deviation. In step S50, the abnormality detection unit 48 calculates an average and a standard deviation of the abnormality degree from the abnormality degree of the learning data in the normal state, for each section of the process. In FIG. 10, for example, an average of “1.08” and a standard deviation of “0.130” of the abnormality degree in “Section 1” are calculated from the learning data in the normal state in “Section 1.”

In step S52, the abnormality detection unit 48 standardizes the abnormality degree for each section of new run, which becomes validation data, using the average and standard deviation of the abnormality degree for each section calculated in step S50. In FIG. 10, for example, the abnormality degree of “1.4” in “Section 1” is standardized using the average of “1.08” and the standard deviation of “0.130” of the abnormality degree for each section calculated in step S50 to obtain a deviation of “2.454.”

In step S54, the abnormality detection unit 48 selects the maximum value for each run from deviations in all of sections obtained in step S52 as the maximum deviation. For example, in FIG. 10, the maximum deviation “2.454” is selected from deviations “2.454, 2.454, and 0.592” in all of the sections of run “Run Number 8.”

A calculation example illustrated in FIG. 10 is merely provided by way of example, and the maximum deviation may be calculated using other methods.

Returning to FIG. 9, the abnormality section rate [%] indicates a rate of sections where an abnormality has been detected among all of sections of the run. For example, when a process is divided into five sections and the number of sections where an abnormality has been detected in a certain Run is three, the abnormality section rate is 60%.

According to the table illustrated in FIG. 9, an operator may easily identify which section of which run an abnormality has been detected. In addition, according to the table illustrated in FIG. 9, an operator may easily grasp an abnormality trend, as will be described later, based on the maximum deviation and the abnormality section rate.

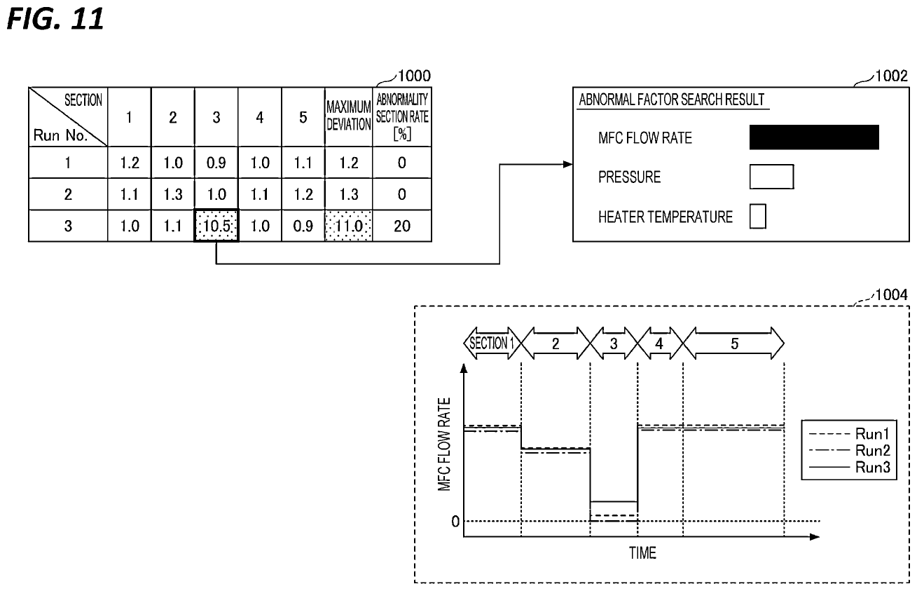

FIG. 11 illustrates an example of searching for the candidates of abnormality factors in a semiconductor manufacturing system according to an embodiment of the present disclosure. A table 1000 illustrated in FIG. 11 illustrates an example in which the maximum deviation in the run of run number “3” where an abnormality has been detected in “section 3” of the process, is high and the abnormality section rate is low. In the example of the table 1000, it is considered that an abnormality has occurred in the sensor value of the sensor 30, which performs special processing in a specific section.

The abnormality factor search unit 50 outputs a ranking 1002 of the sensor 30 of the abnormality factor, for the “section 3” of the run of the run number “3” where an abnormality has been detected, using the abnormality factor search method of “Method 1. Univariate Abnormality” illustrated in FIG. 7. With the ranking 1002 of the sensor 30 of the abnormality factor, it possible to visually output a change in the sensor value of the sensor 30 of a “mass flow controller (MFC) flow rate,” which has a greatest deviation from a sensor value in a normal state.

For example, when a MFC causes a zero-point drift, there is no difference in a displayed flow rate when gas is flowing. Therefore, an operator may not notice any change even if an actual flow rate has changed.

A graph 1004 in FIG. 11 illustrates a change in the sensor value of the sensor 30 of the “MFC flow rate” for each section, and there is no difference in the displayed flow rate due to the influence of the zero-point drift in “section 1,” “section 2,” “section 4” and “section 5” where gas is flowing. Meanwhile, the graph 1004 of FIG. 11 illustrates a difference occurring in the displayed flow rate due to the influence of a zero-point drift in “section 3” where the gas flow rate is set to zero.

As described above, for example, when a mass flow controller (MFC) causes a zero-point drift, the abnormality degree becomes high only in a specific section. Thus, by checking the maximum deviation and the abnormality section rate, the tendency of the abnormality factor that has occurred may be grasped.

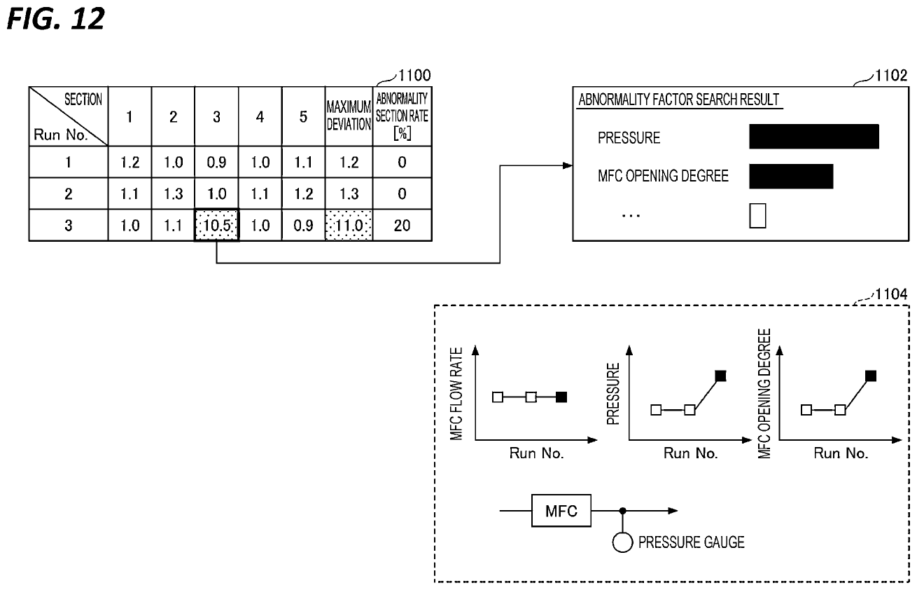

FIG. 12 illustrates an example of searching for the candidates of abnormality factors in a semiconductor manufacturing system according to an embodiment of the present disclosure. A table 1100 illustrated in FIG. 12 illustrates an example in which the maximum deviation of the run of Run number “3” in which an abnormality has been detected in “Section 3” of the process is high and the abnormality section rate is low. In the example of the table 1100, it is considered that an abnormality has occurred in the sensor value of the sensor 30 that performs special processing in a specific section.

The abnormality factor search unit 50 outputs a ranking 1102 of the sensor 30 of an abnormality factor for “Section 3” of the run of Run number “3” where an abnormality has been detected, using the abnormality factor search method of “Method 1. Univariate Abnormality” illustrated in FIG. 7. According to 1102 of the sensor 30 of the abnormality factor, it is possible to visually output a change in the sensor value of the sensor 30 of “pressure,” which has the greatest deviation from a sensor value in a normal state, and a change in the sensor value of the sensor 30 of “MFC opening degree.”

For example, when the MFC causes a zero-point drift, there is no difference in the displayed flow rate when gas is flowing. Therefore, the operator may not notice any change even if an actual flow rate has changed.

If the process does not include a section where a setting value of the MFC flow rate is zero, such as “section 3” illustrated in the graph 1004 of FIG. 11, an abnormality may not be detected from the displayed flow rate. Even in this case, as illustrated in region 1104 of FIG. 12, there is a change in the sensor values of the sensors 30 of the pressure gauge and the MFC opening degree on the same line as a target MFC.

As described above, for example, even if the MFC causes a zero-point drift and the process does not include a section where the setting value of the MFC flow rate is zero, a change occurs in the sensor values of the sensor 30 of the pressure gauge and the MFC opening degree on the same line as the target MFC. Thus, the tendency of the abnormality factor that has occurred may be grasped by checking the maximum deviation and the abnormality section rate.

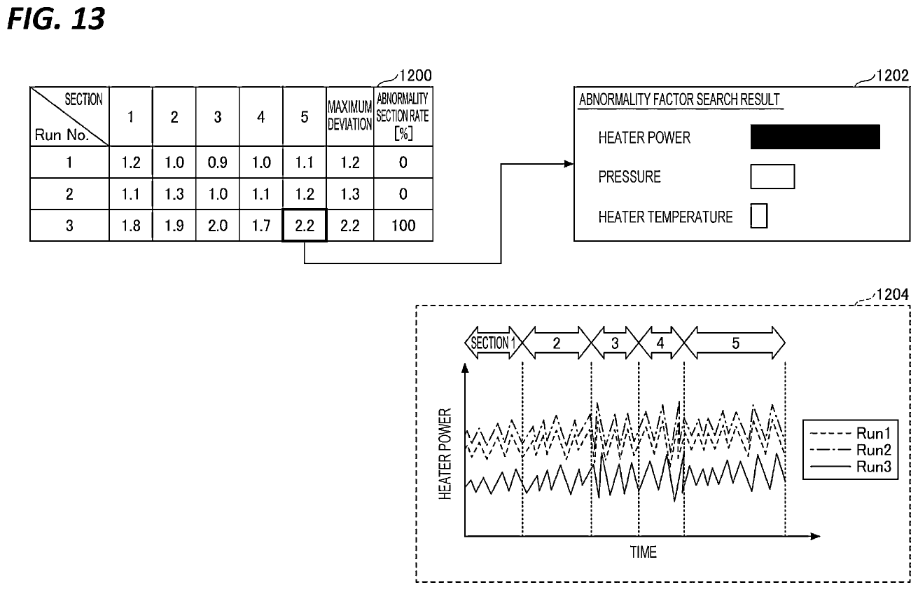

FIG. 13 illustrates an example of searching for the candidates of abnormality factors in a semiconductor manufacturing system according to an embodiment of the present disclosure. A table 1200 illustrated in FIG. 13 illustrates an example where the maximum deviation of the run of Run number “3” is low and the abnormality section rate is high. In the example of the table 1200, it is considered that an abnormality has occurred in the sensor value of the sensor 30 that is not dependent on the processing content of a specific section.

The abnormality factor search unit 50 outputs a ranking 1202 of the sensor 30 of an abnormality factor for “Section 5” of the run of Run number “3” where an abnormality has been detected, using the abnormality factor search method of “Method 1. Univariate Abnormality” illustrated in FIG. 7. With the ranking 1202 of the sensor 30 of the abnormality factor, it is possible to visually output a change in the sensor value of the sensor 30 of “heater power,” which has the greatest deviation from a sensor value in a normal state.

For example, the power of a heater may be degraded due to poor installation of the heater or deterioration over time. A graph 1204 in FIG. 13 illustrates a change in a sensor value of the sensor 30 of the “heater power” for each section, for each run. The graph 1204 in FIG. 13 illustrates a change in the heater power in the run of Run number “3.” As described above, when the heater power is degraded, the abnormality section rate becomes very high. Thus, by checking the maximum deviation and abnormality section rate, the tendency of the abnormality factor that has occurred may be grasped.

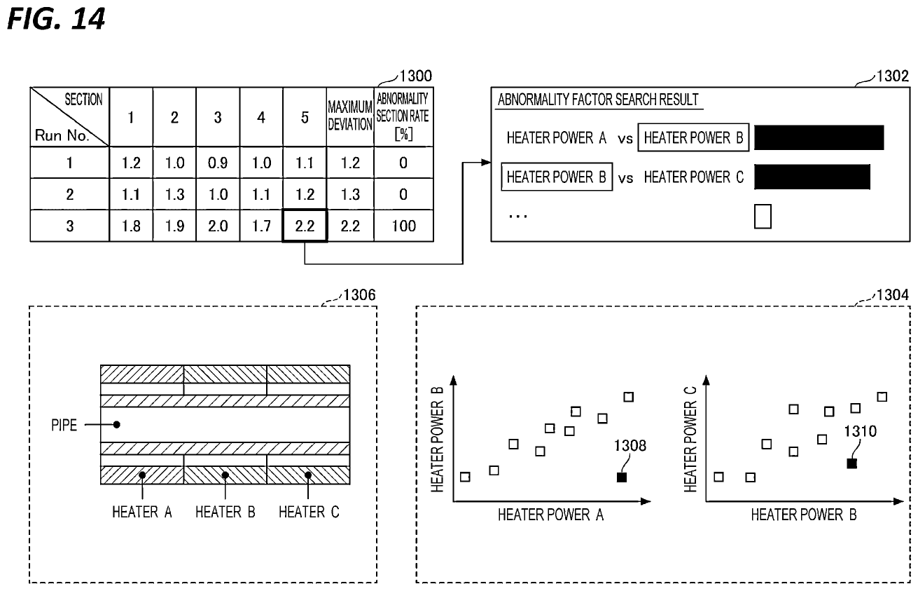

FIG. 14 illustrates an example of searching for the candidates of abnormality factors in a semiconductor manufacturing system according to an embodiment of the present disclosure. As illustrated in region 1306 in FIG. 14, a heater power of a pipe heater is controlled so that a temperature of a sensor value read by the sensor 30 such as a TC becomes a desired temperature.

If the sensor 30 such as the TC is not installed correctly due to poor piping construction, the temperature of the pipe may be abnormal even if a displayed temperature is normal. As such, the heater power is affected by a piping construction state, and thus, has a large variation, so it was sometimes difficult to detect an abnormality based only on the sensor value of the sensor 30 of the heater power.

The abnormality factor search unit 50 outputs a ranking 1302 of the relationship between the sensors 30 of abnormality factors, for “Section 5” of the run of Run number “3” where an abnormality has been detected, using the abnormality factor search method of “Method 2. Correlation Abnormality” illustrated in FIG. 7. With the ranking 1302 of the relationship between the sensors 30 of abnormality factors, it possible to visually output changes in correlations between the sensors 30 of “heater power A vs heater power B” and “heater power B vs heater power C,” which have large changes from a correlation between the sensors 30 in a normal state.

The graph 1304 in FIG. 14 illustrates the correlation between the sensors 30 of the “heater power” for each section, for each run. In graph 1304 in FIG. 14, plots 1308 and 1310 illustrate a collapsed correlation. When the sensor 30 such as a TC is not installed correctly due to poor piping construction, the relationship between the sensors 30 changes. Thus, by checking the correlation abnormality searched for the section of the process where an abnormality has been detected, the tendency of the abnormality factor that has occurred may be grasped.

According to the embodiment, since not only a change in the sensor value of a single sensor 30 but also a change in the correlation between the sensors 30 are considered, it is possible to deal with an abnormality caused by various factors. In addition, according to the embodiment, since a process is divided into sections, multivariate abnormality detection and abnormality factor search are performed for each section, and an abnormality determination result may be output for each section, abnormality factors may be easily considered.

According to the present disclosure, it is possible to provide a technology on searching for a univariate abnormality and a correlation abnormality that are candidates of abnormality factors occurring in a process from sensor values of a plurality of sensors installed in a semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
an acquisition circuitry configured to acquire a plurality of sensor values output from a plurality of sensors installed in a semiconductor manufacturing apparatus, while a process is running in the semiconductor manufacturing apparatus;
an inference circuitry configured to infer an abnormality degree of the process from the plurality of sensor values acquired by the acquisition circuitry, using an abnormality detection model that has learned a correspondence relationship between the plurality of sensor values and the abnormality degree of the process using learning data;
an abnormality detection circuitry configured to detect an abnormality occurring in the process based on the abnormality degree of the process inferred by the inference circuitry;
an abnormality factor search circuitry configured to search for a univariate abnormality and a correlation abnormality that are candidates of abnormality factors occurring in the process, by using a plurality of abnormality factor search methods; and
an abnormality determination result output circuitry configured to output the abnormality in the semiconductor manufacturing apparatus detected by the abnormality detection circuitry, and the univariate abnormality and correlation abnormality searched by the abnormality factor search circuitry, as an abnormality determination result.

2. The information processing apparatus according to claim 1, wherein the process is divided into a plurality of sections,
the abnormality detection model completes learning a correspondence relationship between the plurality of sensor values and the abnormality degree of the process for each of the plurality of sections,
the inference circuitry infers, using the abnormality detection model, an abnormality degree in a section of the process from the plurality of sensor values that is output while the section of the process is running, and
the abnormality detection circuitry detects an abnormality occurring in the section of the process based on the abnormality degree inferred in the section of the process.

3. The information processing apparatus according to claim 2, wherein the abnormality determination result output circuitry displays, for each run of the process, abnormality degrees in the sections of the process, a maximum deviation from an abnormality degree in a normal state, among the abnormality degrees in the sections of the process, and an abnormal section rate of a section in which an abnormality has been detected, among the sections of the process.

4. The information processing apparatus according to claim 3, wherein the abnormality determination result output circuitry displays, for a run of the process where the abnormality has been detected, the plurality of sensors according to a difference between the sensor value in a normal state and the sensor value of the process where the abnormality has been detected, as a univariate abnormality that is a candidate of an abnormality factor that has occurred in the process.

5. The information processing apparatus according to claim 3, wherein the abnormality determination result output circuitry displays, for a run of the process where the abnormality has been detected, a correlation of the plurality of sensors according to a difference from a correlation of the plurality of sensors in a normal state, as a correlation abnormality that is a candidate of an abnormality factor that has occurred in the process.

6. The information processing apparatus according to claim 2, wherein the abnormality determination result output circuitry displays, among the sections of the process, a section of the process having an abnormal value equal to or greater than a threshold in a visually different manner from a section of the process having an abnormal value less than the threshold.

7. An abnormality detection method comprising:
acquiring a plurality of sensor values outputted from a plurality of sensors installed in a semiconductor manufacturing apparatus, while a process is running in the semiconductor manufacturing apparatus;
inferring an abnormality degree of the process from the acquired plurality of sensor values, using an abnormality detection model that has learned a correspondence relationship between the plurality of sensor values and the abnormality degree of the process using learning data; and
detecting an abnormality occurring in the process based on the abnormality degree of the process inferred in the inferring;
searching for a univariate abnormality and a correlation abnormality that are candidates of abnormality factors occurring in the process, using a plurality of abnormality factor search methods; and
outputting the abnormality in the semiconductor manufacturing apparatus detected in the detecting, and the univariate abnormality and correlation abnormality searched in the searching as an abnormality determination result.

8. A semiconductor manufacturing system comprising:
a semiconductor manufacturing apparatus, and
an information processing apparatus including:
an acquisition circuitry configured to acquire a plurality of sensor values output from a plurality of sensors installed in the semiconductor manufacturing apparatus, while a process is running in the semiconductor manufacturing apparatus;
an inference circuitry configured to infer an abnormality degree of the process from the plurality of sensor values acquired by the acquisition circuitry, using an abnormality detection model that has learned a correspondence relationship between the plurality of sensor values and the abnormality degree of the process using learning data;
an abnormality detection circuitry configured to detect an abnormality occurring in the process based on the abnormality degree of the process inferred by the inference circuitry;
an abnormality factor search circuitry configured to search for a univariate abnormality and a correlation abnormality that are candidates of abnormality factors occurring in the process, by using a plurality of abnormality factor search methods; and
an abnormality determination result output circuitry configured to output the abnormality in the semiconductor manufacturing apparatus detected by the abnormality detection circuitry and the univariate abnormality and correlation abnormality searched by the abnormality factor search circuitry, as an abnormality determination result.
